(19) United States
(12) Patent Application Publication
(10) Pub. No.: US 2025/0210456 A1
(43) Pub. Date: Jun. 26, 2025

(54) Active Cooling for Heterogenous Packages

(71) Applicant: Intel Corporation, Santa Clara, CA (US)

(72) Inventors: Eduardo De Mesa, Munich (DE); Vishnu Prasad, Munich (DE); Bernd Waidhas, Pettendorf (DE); Carlton Hanna, Santa Clara, CA (US); Pouya Talebbeydokhti, Mesa, AZ (US); Jan Proschwitz, Riesa (DE); Sonja Koller, Lappersdorf (DE); Stefan Reif, Munich (DE)

(21) Appl. No.: 18/389,854

(22) Filed: Dec. 20, 2023

(51) Int. Cl. H01L 23/467; H01L 23/00; H01L 25/18; H10B 80/00

(52) U.S. Cl. CPC H01L 23/467; H01L 25/18; H10B 80/00; H01L 24/16; H01L 2224/16225

(57) ABSTRACT

A present chip assembly may have a matrix of dies and cooling devices that may provide active cooling within a package. The cooling devices may provide airflow directed to spaces that are provided between dies placed on a support platform. The placement of the cooling devices may be optimized to provide active cooling at hot spot areas of the package.

### BACKGROUND

For integrated circuit design and fabrication, the need to improve performance and lower costs are constant challenges. To provide greater performance, newly developed processors, memory, and other ICs are more powerful and can process data and transfer it around a system at increasing speeds.

In addition, the use of heterogeneous integration has emerged as an approach to provide enhanced functionality and improved operating characteristics. It may be used to support numerous packaging technologies, such as system-in-package, 2.5D and 3D use of through-silicon-vias (TSVs), silicon interposer structures, and high-density fan-out (HDFO) packages that allow dies made with different silicon process nodes and operate in a single device. Heterogenous packaging offers an opportunity to greatly improve product performance, i.e., speed. However, the result of this increased speed is the loss of efficiency and power due to the generation of heat.

The rising performance of heterogenous packages presents unique challenges on thermal management requirements due to the complex configurations of multiple vertically stacked dies, adjacent die placements, higher power densities, increases in physical size/geometry, and power delivery requirements. Accordingly, the thermal management issues for heterogeneous packages must be addressed to ensure high functionality and high product reliability.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a top view of a layout of chiplets and cooling devices, and FIG. 1A shows a cross-section view of one of the cooling devices according to an aspect of the present disclosure;

FIG. 2 shows another exemplary representation of a top view of a layout of chiplets and cooling devices, and FIG. 2A shows a cross-section view of one of the cooling devices according to an aspect of the present disclosure;

FIGS. 3A and 3B show exemplary representations of cross-views of a chip assembly and a heterogeneous package assembly, respectively, with cooling devices according to an aspect of the present disclosure;

FIGS. 4A and 4B show exemplary representations of cross-views of another chip assembly and another heterogeneous package assembly, respectively, with cooling devices according to another aspect of the present disclosure;

FIGS. 5A and 5B show exemplary representations of cross-views of yet another chip assembly and yet another heterogeneous package assembly, respectively, with cooling devices according to yet another aspect of the present disclosure;

FIG. 6 shows an exemplary representation of controls for cooling devices according to an aspect of the present disclosure; and

FIG. 7 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present chip assembly may have a matrix of dies and cooling devices that may provide active cooling within a package. The cooling devices may provide airflow directed to spaces that are provided between dies placed on a support platform. The placement of the cooling devices may be optimized to provide active cooling at hot spot areas of the package.

The present disclosure is directed to a chip assembly having a support platform, a plurality of dies disposed on the support platform, for which each of the plurality of dies is separated from another die by air channels, and a plurality of cooling devices disposed on the support platform. In an aspect, the plurality of cooling devices has air inlets and air outlets, for which air outlets are configured to direct airflow into the air channels.

The present disclosure is also directed to a method that includes providing a support platform, providing a plurality of dies, and disposing the plurality of dies on the support platform, for which each of the plurality of dies is separated from other dies by an air channel, providing a plurality of cooling devices, for which the plurality of cooling devices includes air inlets and air outlets, and disposing the plurality of cooling devices on the support platform to be proximal to the plurality of dies and configuring the air outlets to direct airflow into the air channels.

The present disclosure is further directed to a heterogenous package having a chip assembly having a support platform, a plurality of dies disposed on the support platform, for which each of the plurality of dies is separated from other dies by air channels, and a plurality of cooling devices disposed on the support platform, the plurality of cooling devices having air inlets and air outlets, for which air outlets are configured to direct airflow into the air channels. In an aspect, the plurality of dies includes chip and/or chiplets and memory stacks and the plurality of cooling devices includes MEMS airflow devices.

The technical advantages of the present disclosure include, but are not limited to:
(i) providing chip assemblies of chips and/or chiplets that have distributed cooling devices disposed on a support platform;
(ii) providing localized and active heat removal for 2×D/2.5D/3D and heterogeneous packages, and that may be used together with other heat removal methods; and
(iii) providing thermal solutions that may improve thermal management, product functionality, and reliability performance.

To more readily understand and put into practical effect the present chip assembly and methods for localizing heat removal therefrom, which may provide improved device performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

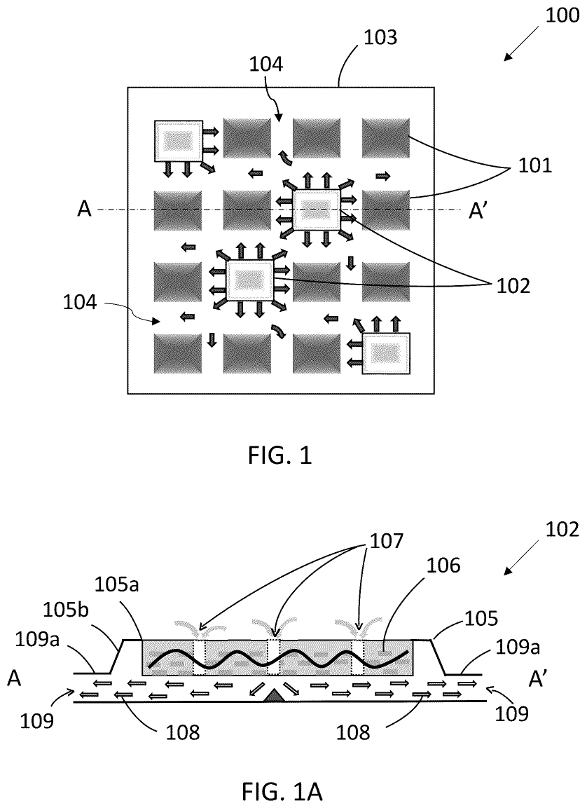

FIG. 1 shows an exemplary representation of a top view of a layout of a chip assembly 100 that includes a plurality of dies 101 and a plurality of cooling devices 102, which together may be disposed on a support platform 103 according to an aspect of the present disclosure. The plurality of dies may include chips, such as logic circuits, a central processing unit (CPU), a graphical processing unit (GPU), memory dies, and chiplets that have a variety of different IP blocks. The plurality of dies 101 may be configured in a layout that purposefully provides air channels or lanes 104 between the dies for circulating air to remove heat and provide localized cooling for the chip assembly 100 to reduce the temperature of a heterogeneous package. The plurality of cooling devices 102 may include a micro-electromechanical systems (MEMS) airflow device (which may provide vibrating membranes as an air pump), a 3D printed airflow device (which may provide a micro fan-structure as an air pump), etc. One or more of the cooling devices 102 may be placed at hot spot areas of the chip assembly 100, which may be determined during prototype testing or by simulations, to optimize the removal of heat. The support platform 103 may be an interposer or a printed circuit board.

In FIG. 1A, the cooling device 102 is a MEMS airflow device 102, which is shown as a cross-section view along section line A-A′ of FIG. 1. The MEMS airflow device 102 includes a body 105 that houses an air pump 106, which includes a series of silicon membranes that vibrate at ultrasonic frequencies, that creates pulsating jets to draw in air from outside the body 105 through air inlets 107, which are openings in a first surface 105a of the body 105 of the MEMS airflow device 102. In an aspect, the first surface 105a of the body 105 may be a top or upper surface. In this aspect, an airflow 108 may be generated by the air pump 106, which is positioned between the air inlets 107 and directional air outs 109, and directed to the air outlets 109, which may be positioned on a second surface 105b. The airflow 108 may be further directed, at a die level, via conduits 109a positioned facing the air channels 104 between the plurality of dies 101 to remove heat from the plurality of dies 101. In an aspect, the second surface 105b of the body 105 may be a side surface. The positions of the MEMS airflow devices 102 may be configured to be interspersed or embedded among the plurality of dies on the support platform as shown in FIG. 1A.

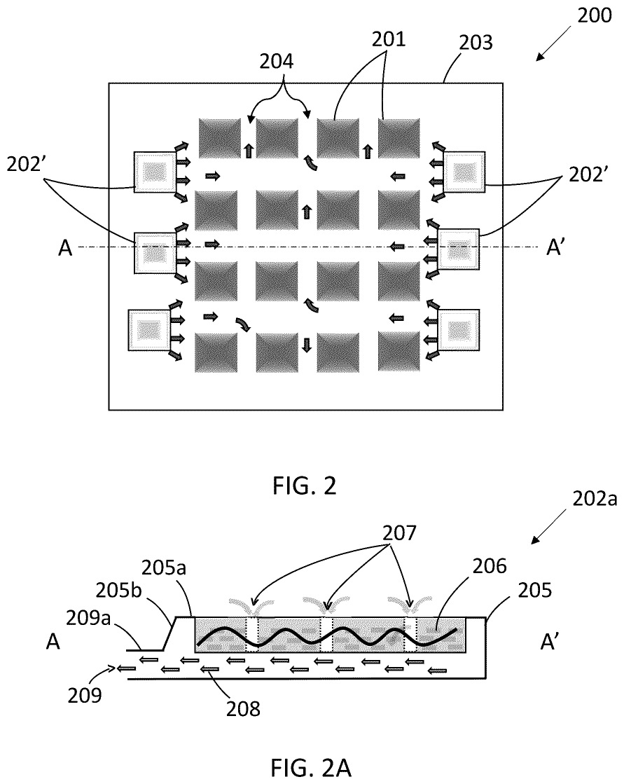

FIG. 2 shows another exemplary representation of a top view of a layout of chiplets and cooling devices, and FIG. 2A shows a cross-section view of one of the cooling devices according to an aspect of the present disclosure. In this aspect, a chip assembly 200 may include a plurality of dies 201 and a plurality of cooling devices 202, which together may be disposed on a support platform 203. The plurality of dies may include dies having logic circuits, a central processing unit (CPU), a graphical processing unit (GPU), memory devices, and chiplets having a variety of different IP blocks. The plurality of dies 201 may be configured in a layout that purposefully provides air channels or lanes 204 between the dies for circulating air to remove heat and provide localized cooling for the chip assembly 200. The plurality of cooling devices 202 may include a micro-electromechanical systems (MEMS) airflow device (which may provide vibrating membranes as an air pump), a 3D printed airflow device (which may provide a micro fan-structure as an air pump), etc. The support platform 203 may be an interposer or a package substrate.

In FIG. 2A, the cooling device 202 is a MEMS airflow device 202 shown as a cross-section view along section line A-A′ of FIG. 2. The MEMS airflow device 202 includes a body 205 that houses an air pump 206, which includes a series of silicon membranes that vibrate at ultrasonic frequencies, that creates pulsating jets to draw in air from outside the body 205 through air inlets 207, which are openings in a first surface 205a of the body 205 of the MEMS airflow device 202. In an aspect, the first surface 205a of the body 205 may be a top or upper surface. In this aspect, an airflow 208 may be generated by the air pump 206, which is positioned between the air inlets 207 and air outs 209, and directed to directional air outlets 209, which be positioned on a second surface 205b of the body 205. In an aspect, the second surface 205b of the body 205 may be a side surface. The airflow 208 may be directed at a die level via a conduit 209a positioned to face into the air channels 204 between the dies 201 to remove heat from the dies 201. The positions of the MEMS airflow devices 202 may be configured to be at the peripheries of the plurality of dies on the support platform, as shown in FIG. 2A, to optimize the removal of heat in certain design layouts.

Although the plurality of dies in FIGS. 1 and 2 above are shown as being configured with air channels that have a grid-like layout or matrix and the dies have the same size, it should be understood that a chip assembly may have dies of different sizes, and as a result, the air channels may have an irregular layout, i.e., not in straight lines. In addition, while the use of the present cooling devices may be principally directed to heterogeneous package assemblies and 2.5D/3D packages, they may be applied to 2D and 2×D packages as well.

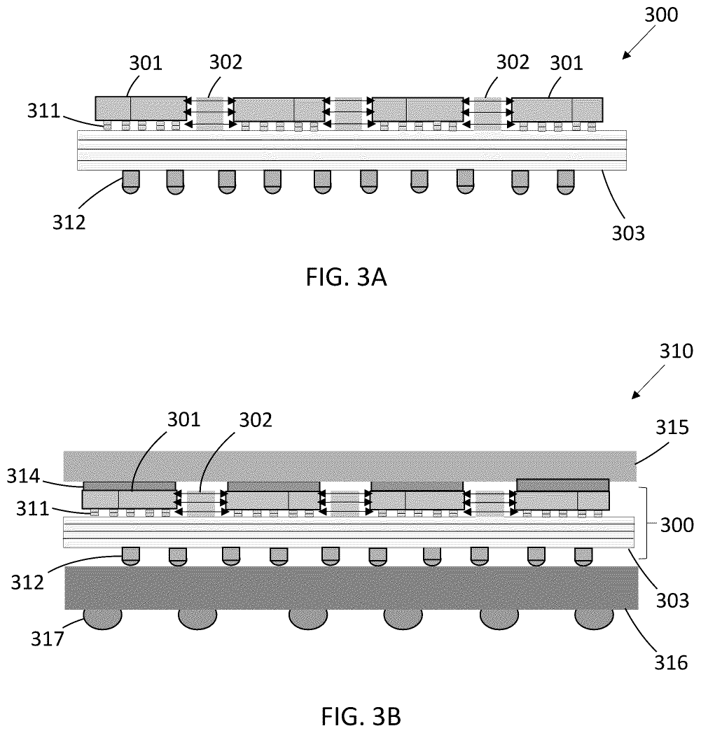

FIGS. 3A and 3B show exemplary representations of cross-views of a chip assembly 300 and a heterogeneous package assembly 310, respectively, with MEMS airflow devices 302 according to an aspect of the present disclosure. In FIG. 3A, the chip assembly 300 may include a plurality of dies 301 and a plurality of MEMS 302, which together may be disposed on an interposer 303. The MEMS airflow devices 302 may be configured to be interspersed or embedded among the plurality of dies 301 on the interposer 303 and provide localized cooling for the heterogeneous package assembly 310. In an aspect, the plurality of dies 301 may have a plurality of solder interconnects 311 for coupling with the interposer 303, and the interposer 303 may have a plurality of solder interconnects 312. In another aspect, the MEMS airflow devices 302 may be surface mounted on the interposer 303.

In FIG. 3B, the heterogeneous package assembly 310 may be provided with a heat spreader 315 that is thermally coupled by a thermal interface material (TIM) 314 to the plurality of dies 301 on the chip assembly 300. The chip assembly 300 may be coupled to a package substrate 316 by the plurality of solder interconnects 312. In addition, the package substrate 316 may have a plurality of solder balls 317 for connection with a further support platform, e.g., a printed circuit board (not shown).

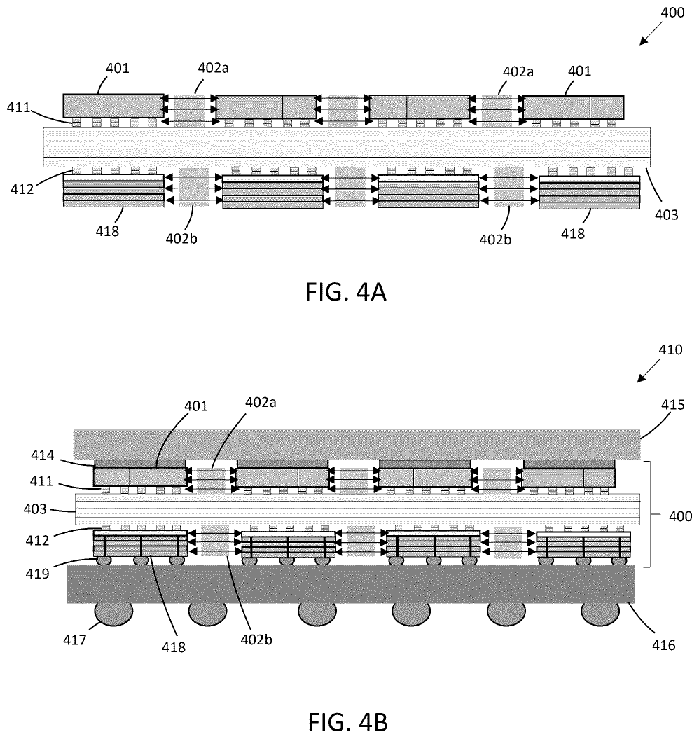

FIGS. 4A and 4B show exemplary representations of cross-views of another chip assembly 400 and a heterogeneous package assembly 410, respectively, with MEMS airflow devices according to another aspect of the present disclosure. In FIG. 4A, the chip assembly 400 may include a plurality of dies 401 and a plurality of MEMS airflow devices 402a, which together may be disposed on an upper surface of an interposer 403, and a plurality of stacked memory devices 418 and a plurality of MEMS airflow devices 402b, which together may be disposed on a lower surface of the interposer 403.

The MEMS airflow devices 402a and 402b may be configured to be interspersed or embedded among the plurality of dies 401 and plurality of stacked memory devices 418, respectively, on the interposer 403 and provide localized cooling for the heterogeneous package assembly 410. In an aspect, the plurality of dies 401 may have a plurality of solder interconnects 411 for coupling with the interposer 403, and the plurality of stacked memory devices 418 may have a plurality of solder interconnects 412 for coupling with the interposer 403. In another aspect, the MEMS airflow devices 402a and 402b may be surface mounted on the interposer 303.

In FIG. 4B, the heterogeneous package assembly 410 may be provided with a heat spreader 415 that is thermally coupled by a thermal interface material (TIM) 414 to the plurality of dies 401 on the chip assembly 400. The chip assembly 400 may be coupled to a package substrate 416 by the plurality of solder balls 419 connected to the plurality of stacked memory devices 418. In addition, the package substrate 416 may have a plurality of solder balls 417 for connection with a further support platform, e.g., a printed circuit board (not shown).

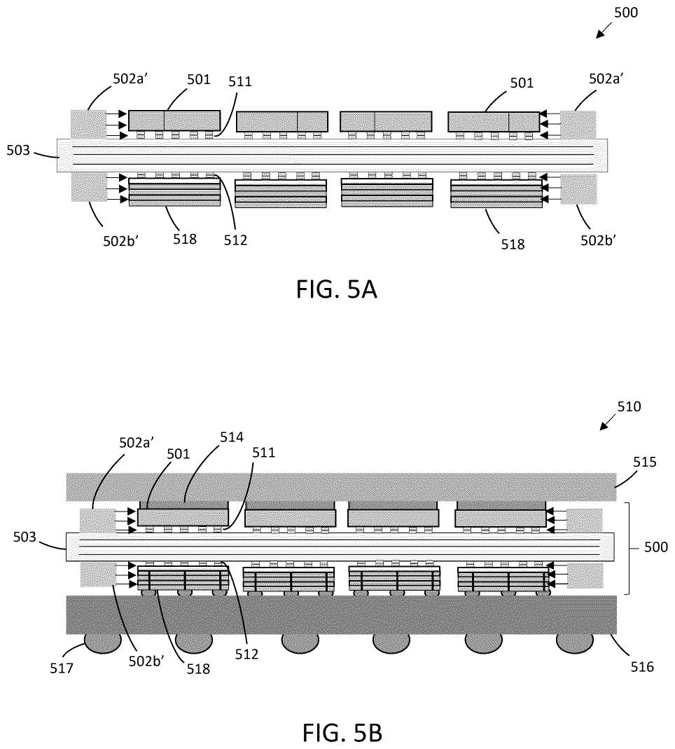

FIGS. 5A and 5B show exemplary representations of cross-views of yet another chip assembly 500 and a heterogeneous package assembly 510, respectively, with MEMS airflow devices according to yet another aspect of the present disclosure.

In FIG. 5A, the chip assembly 500 may include a plurality of dies 501 and a plurality of MEMS airflow devices 502a′, which together may be disposed on an upper surface of an interposer 503, and a plurality of stacked memory devices 518 and a plurality of MEMS airflow devices 502b′, which together may be disposed on a lower surface of the interposer 503. The MEMS airflow devices 502a′ may be configured to be positioned at the periphery of the plurality of dies 501 on the upper surface of the interposer 503, and the MEMS airflow devices 502b′ may be configured to be positioned at the periphery of the plurality of stacked memory devices 518 on the lower surface of the interposer 503 and provide localized cooling for the heterogeneous package assembly 510. In an aspect, the plurality of dies 501 may have a plurality of solder interconnects 511 for coupling with the interposer 503, and the plurality of stacked memory devices 518 may have a plurality of solder interconnects 512 for coupling with the interposer 503. In another aspect, the MEMS airflow devices 502a and 502b may be surface mounted on the interposer 303.

In FIG. 5B, the heterogeneous package assembly 510 may be provided with a heat spreader 515 that is thermally coupled by a thermal interface material (TIM) 514 to the plurality of dies 501 on the chip assembly 500. The chip assembly 500 may be coupled to a package substrate 516 by the plurality of solder balls 519 connected to the plurality of stacked memory devices 518. In addition, the package substrate 516 may have a plurality of solder balls 517 for connection with a further support platform, e.g., a printed circuit board (not shown).

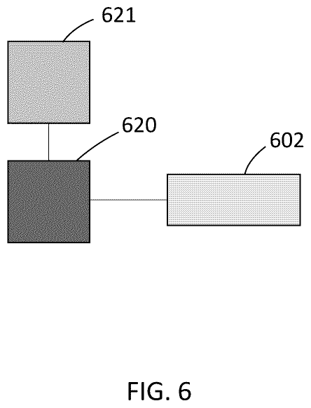

In the above FIGS. 5A, 5B, 6A, and 6B, it should be understood that the positions of the chips, chiplets, and stacked memory dies may be alternatively positioned on either the upper or lower surfaces of a support platform depending on a particular layout design of a package, i.e., one or more chips and chiplets may be placed on the lower surface and/or one or more stacked memory dies may be placed on the upper surface of the support platform.

FIG. 6 shows an exemplary representation of controls for cooling devices according to an aspect of the present disclosure. In this aspect, a cooling device 602 may be coupled with a processor 620 and a temperature sensor 621. The temperature sensor 621 may be several temperature sensors that are placed at heat-sensitive or heat-generating locations. The temperature sensor 621 may monitor the heat generated by a die (not shown) in a heterogenous package (not shown), and if the heat is above a threshold, the processor 620 may activate the cooling device 602 to provide an airflow to remove the heat. The processor 620 may be one of a plurality of dies on a support platform, which has functionality that is shared with other devices.

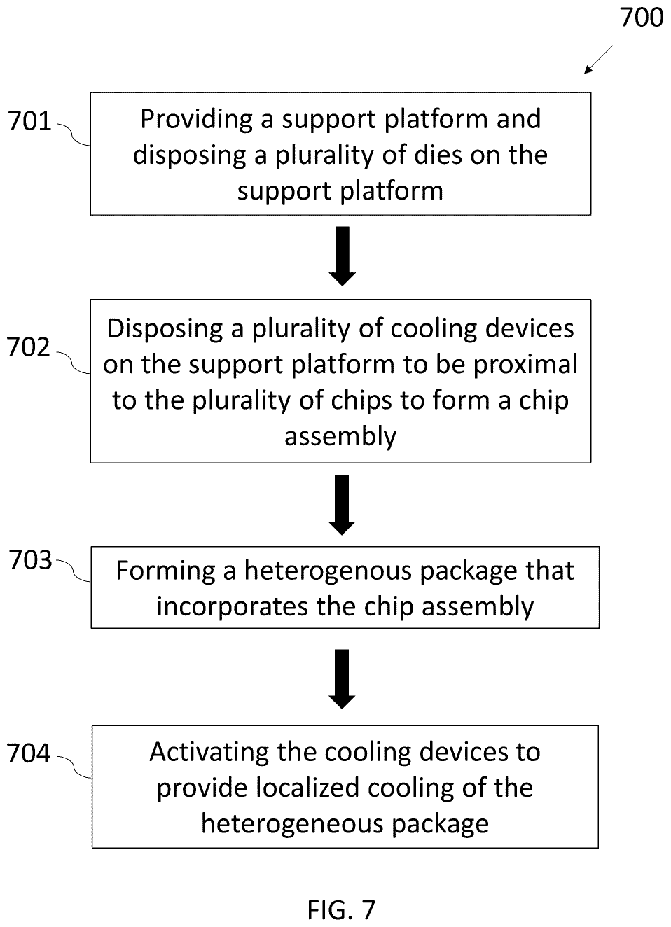

FIG. 7 shows a simplified flow diagram for an exemplary method according to an aspect of the present disclosure.

The operation 701 may be directed to providing a support platform and disposing a plurality of chips on the support platform.

The operation 702 may be directed to disposing a plurality of cooling devices on the support platform to be proximal to the plurality of chips to form a product assembly.

The operation 703 may be directed to forming a heterogenous package that incorporates the product assembly.

The operation 704 may be directed to activating the cooling devices to provide localized cooling of the heterogeneous package assembly.

It will be understood that any property described herein for a particular heterogeneous package assembly and method for localized cooling of the plurality of dies may also hold for any package assembly using the present cooling devices described herein. It will also be understood that any property described herein for a specific method may hold for any of the methods described herein. Furthermore, it will be understood that for any heterogenous package assembly configured with cooling devices and the methods described herein, not necessarily all the components or operations described will be shown in the accompanying drawings or method, but only some (not all) components or operations may be disclosed.

To more readily understand and put into practical effect the localized cooling of heterogeneous package assemblies having present cooling devices, they will now be described by way of examples. For the sake of brevity, duplicate descriptions of features and properties may be omitted.

### EXAMPLES

Example 1 provides an assembly including a support platform, a plurality of dies disposed on the support platform, for which each of the plurality of dies is separated from other dies by air channels, and a plurality of cooling devices disposed on the support platform, for which the plurality of cooling devices includes a body with air inlets that are disposed at a first surface of the body and air outlets that are disposed at a second surface of the body, for which the body houses an air pump that is disposed between the air inlets and the air outs, and for which each of the air outlets comprises a conduit positioned in a direction facing the air channels.

Example 2 may include the assembly of example 1 and/or any other example disclosed herein, for which the plurality of dies includes chips and/or chiplets.

Example 3 may include the assembly of example 1 and/or any other example disclosed herein, for which the plurality of dies includes memory stacks.

Example 4 may include the assembly of example 1 and/or any other example disclosed herein, for which the plurality of cooling devices includes MEMS airflow devices.

Example 5 may include the assembly of example 1 and/or any other example disclosed herein, for which the support platform includes an interposer.

Example 6 may include the assembly of example 1 and/or any other example disclosed herein, for which the plurality of cooling devices is interspersed among the plurality of dies on the support platform.

Example 7 may include the assembly of example 1 and/or any other example disclosed herein, for which the plurality of cooling devices is positioned on a periphery of the plurality of dies on the support platform.

Example 8 may include the assembly of example 1 and/or any other example disclosed herein, for which the plurality of cooling devices is coupled to a processor.

Example 9 may include the assembly of example 1 and/or any other example disclosed herein, for which the plurality of cooling devices is coupled to a temperature sensor.

Example 10 provides a method including providing a support platform, providing a plurality of dies and disposing the plurality of dies on the support platform, for which each of the plurality of dies is separated from another die by an air channel, providing a plurality of cooling devices, for which the plurality of cooling devices includes a body with air inlets that are disposed at a first surface of the body and air outlets that are disposed at a second surface of the body, and wherein the body houses an air pump that is disposed between the air inlets and the air outs, disposing the plurality of cooling devices on the support platform to be proximal to the plurality of dies, producing an airflow using the air pump by drawing in air via the air inlets and pushing out air through the air outlets via conduits, and removing heat by directing airflow from the conduits into the air channels.

Example 11 may include the method of example 10 and/or any other example disclosed herein, which further includes monitoring the plurality of dies for heat generated by the plurality of dies using a temperature sensor.

Example 12 may include the method of example 11 and/or any other example disclosed herein, which further includes activating one or more of the plurality cooling devices to provide airflow into the air channels using a processor.

Example 13 provides a package including a chip assembly having a support platform, a plurality of dies disposed on the support platform, for which each of the plurality of dies is separated from other dies by air channels, and a plurality of cooling devices disposed on the support platform, for which the plurality of cooling devices including a body with air inlets that are disposed at a first surface of the body and air outlets that are disposed at a second surface of the body, for which the body houses an air pump that is disposed between the air inlets and the air outs, and each of the air outlets includes a conduit positioned in a direction facing the air channels.

Example 14 may include the package of example 13 and/or any other example disclosed herein, for which the plurality of dies includes chips and/or chiplets.

Example 15 may include the package of example 13 and/or any other example disclosed herein, for which the plurality of dies includes memory stacks.

Example 16 may include the package of example 13 and/or any other example disclosed herein, for which the plurality of cooling devices includes MEMS airflow devices.

Example 17 may include the package of example 13 and/or any other example disclosed herein, for which the support platform includes an interposer.

Example 18 may include the package of example 13 and/or any other example disclosed herein, for which the plurality of cooling devices is positioned interspersed among the plurality of dies on the support platform.

Example 19 may include the package of example 13 and/or any other example disclosed herein, for which the plurality of cooling devices is positioned on a periphery of the plurality of dies on the support platform.

Example 20 may include the package of example 13 and/or any other example disclosed herein, further includes a heat spreader coupled to the plurality of dies.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. An assembly comprising:
a support platform;
a plurality of dies disposed on the support platform, wherein each of the plurality of dies is separated from other dies by air channels; and
a plurality of cooling devices disposed on the support platform, wherein the plurality of cooling devices comprises a body with air inlets that are disposed at a first surface of the body and air outlets that are disposed at a second surface of the body,
wherein the body houses an air pump that is disposed between the air inlets and the air outs, and wherein each of the air outlets comprises a conduit positioned in a direction facing the air channels.

2. The assembly of claim 1, wherein the plurality of dies comprises chips and/or chiplets.

3. The assembly of claim 1, wherein the plurality of dies comprises memory stacks.

4. The assembly of claim 1, wherein the plurality of cooling devices comprises MEMS airflow devices.

5. The assembly of claim 1, wherein the support platform comprises an interposer.

6. The assembly of claim 1, wherein the plurality of cooling devices is interspersed among the plurality of dies on the support platform.

7. The assembly of claim 1, wherein the plurality of cooling devices is positioned on a periphery of the plurality of dies on the support platform.

8. The assembly of claim 1, wherein the plurality of cooling devices is coupled to a processor.

9. The assembly of claim 1, wherein the plurality of cooling devices is coupled to a temperature sensor.

10. A method comprising:
providing a support platform;
providing a plurality of dies and disposing the plurality of dies on the support platform, wherein each of the plurality of dies is separated from another die by an air channel;
providing a plurality of cooling devices, wherein each of the plurality of cooling devices comprises a body with air inlets that are disposed at a first surface of the body and air outlets that are disposed at a second surface of the body, and wherein the body houses an air pump that is disposed between the air inlets and the air outs;
disposing the plurality of cooling devices on the support platform to be proximal to the plurality of dies;
producing an airflow using the air pump by drawing in air via the air inlets and pushing out air through the air outlets via conduits; and
removing heat by directing airflow from the conduits to the air channels.

11. The method of claim 10, further comprises monitoring the plurality of dies for heat generated by the plurality of dies using a temperature sensor.

12. The method of claim 11, further comprises activating one or more of the plurality cooling devices to provide airflow into the air channels using a processor.

13. A package comprising:
a chip assembly comprising:
a support platform;
a plurality of dies disposed on the support platform, wherein each of the plurality of dies is separated from other dies by air channels; and
a plurality of cooling devices disposed on the support platform, wherein the plurality of cooling devices comprising a body with air inlets that are disposed at a first surface of the body and air outlets that are disposed at a second surface of the body,
wherein the body houses an air pump that is disposed between the air inlets and the air outs, and
wherein each of the air outlets comprises a conduit positioned in a direction facing the air channels.

14. The package of claim 13, wherein the plurality of dies comprises chips and/or chiplets.

15. The package of claim 13, wherein the plurality of dies comprises memory stacks.

16. The package of claim 13, wherein the plurality of cooling devices comprises MEMS airflow devices.

17. The package of claim 13, wherein the support platform comprises an interposer.

18. The package of claim 13, wherein the plurality of cooling devices is positioned interspersed among the plurality of dies on the support platform.

19. The package of claim 13, wherein the plurality of cooling devices is positioned on a periphery of the plurality of dies on the support platform.

20. The package of claim 13, further comprises a heat spreader coupled to the plurality of dies.
